(19) United States
(12) Patent Application Publication
(10) Pub. No.: US 2009/0079013 A1
(43) Pub. Date: Mar. 26, 2009

(54) MOS TRANSISTOR AND METHOD FOR MANUFACTURING THE TRANSISTOR

(75) Inventor: Jeong Ho KIM, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/202,936

(22) Filed: Sep. 2, 2008

(30) Foreign Application Priority Data
Sep. 20, 2007 (KR) 10-2007-0095902

(51) Int. Cl. H01L 29/00; H01L 21/76

(52) U.S. Cl. 257/402; 438/425; 257/E29.001; 257/E21.54

(57) ABSTRACT

A MOS transistor and a method for manufacturing the transistor are disclosed. The method for manufacturing the MOS transistor may include successively stacking a pad oxide layer and a mask layer on a semiconductor substrate, patterning the pad oxide layer and the mask layer, to expose a trench forming region of the semiconductor substrate, forming a trench in the semiconductor substrate by etching the exposed trench forming region, and forming an anti-diffusion layer and an oxide layer over the entire surface of the semiconductor substrate including the trench. This method can reduce leakage current, among other things, resulting in improved characteristics of transistor products.

### CROSS-REFERENCE TO RELATED APPLICATION

This application claims priority to Korean Patent Application No. 10-2007-0095902, filed on, Sep. 20, 2007, which is incorporated herein by reference in its entirety.

### BACKGROUND

1. Field of the Invention

Embodiments of the present invention relate to semiconductor devices, and more particularly, to a MOS transistor and a method for manufacturing the transistor.

2. Discussion of the Related Art

Leakage current of general Metal Oxide Semiconductor (MOS) transistors will be described hereinafter with reference to the accompanying drawings.

FIG. 1 is a graph illustrating current-voltage characteristics of an NMOS transistor. In particular, the graph illustrates leakage current in a sub-threshold region when a drain voltage Vd is 0.1V.

In FIG. 1, the abscissa represents a gate voltage in volts, and the ordinate represents a drain current in amperes. In addition, “HUMP” represents a case where leakage current occurs, and “NO HUMP” represents a case where no leakage current occurs.

FIG. 2 is a view illustrating an edge transistor and a main transistor. In FIG. 2, a thick arrow represents a main transistor, and a thin arrow represents an edge transistor.

Referring to voltage-current characteristics of an NMOS transistor shown in FIG. 1, a case where leakage current occurs in a sub-threshold region can be compared to a case where no leakage current occurs. The occurrence of leakage current in the sub-threshold region may cause a greater consumption of electric power than the case where no leakage current occurs.

The leakage current may be caused by various processes. These associated processes, as shown in FIG. 2, result in an edge transistor or parasitic transistor. It is known that a low threshold voltage in a sub-threshold region of the edge transistor or the parasitic transistor causes leakage current.

More specifically, causes of the edge transistor as shown in FIG. 2 are, for example, as follows: first, thinning of a gate oxide layer in the top corner of a Shallow Trench Isolation (STI) feature; second, a low well dopant concentration of an edge transistor due to a dopant in a well interface, for example, boron, being segregated toward a field oxide layer during subsequent thermal processing; and third, positive (+) or negative (−) charges trapped in a gate oxide layer or field oxide layer.

Generally, subsequent to an etching process to form an STI feature, a high-temperature thermal process, such as an STI linear oxidation process, and an STI gap-fill densification process are performed. These subsequent processes cause boron, used as a well dopant for a High Voltage (HV) NMOS, to diffuse or move toward a linear oxide layer and a field oxide layer. Thereby, the edge transistor as shown in FIG. 2 is caused due to the diffusion/movement of boron, resulting in an increased leakage current.

In particular, an HV NMOS has a lower boron concentration than other NMOS devices. Therefore, if boron diffuses toward an oxide layer during subsequent processing, the HV NMOS may be subject to more problems than other NMOS devices.

### SUMMARY OF SOME EXAMPLE EMBODIMENTS

In general, example embodiments of the present invention relate to a MOS transistor and a method for manufacturing the transistor that substantially obviate one or more problems due to limitations and disadvantages of the related art.

For example, according to an example MOS transistor and method for manufacturing the same, leakage current can be reduced, among other things.

A method for manufacturing a Metal Oxide Semiconductor (MOS) transistor may comprise successively stacking a pad oxide layer and a mask layer on a semiconductor substrate; patterning the pad oxide layer and the mask layer, to expose a trench forming region of the semiconductor substrate; forming a trench in the semiconductor substrate by etching the exposed trench forming region; and forming an anti-diffusion layer and an oxide layer over the entire surface of the semiconductor substrate including the trench.

In accordance with another embodiment, there is provided a Metal Oxide Semiconductor (MOS) transistor comprising: a pad oxide layer and a mask layer successively stacked on a semiconductor substrate and having an opening to expose the semiconductor substrate; a trench formed by etching a partial region of the semiconductor substrate exposed through the opening; an anti-diffusion layer formed inside the trench and the opening and also, formed on the mask layer; an oxide layer formed on the anti-diffusion layer inside the trench and the opening; and an insulating layer gap-filled in the trench and the opening including the partial anti-diffusion layer and the overall oxide layer.

In accordance with another embodiment, there is provided a Metal Oxide Semiconductor (MOS) transistor comprising: a pad oxide layer and a mask layer successively stacked on a semiconductor substrate and having an opening to expose the semiconductor substrate; a trench formed by etching a partial region of the semiconductor substrate exposed through the opening; an oxide layer formed inside the trench and the opening and also, formed on the mask layer; an anti-diffusion layer formed on the oxide layer; and an insulating layer gap-filled in the trench and the opening including the partial anti-diffusion layer and the partial oxide layer.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIG. 1 is a graph illustrating current-voltage characteristics of an NMOS transistor;

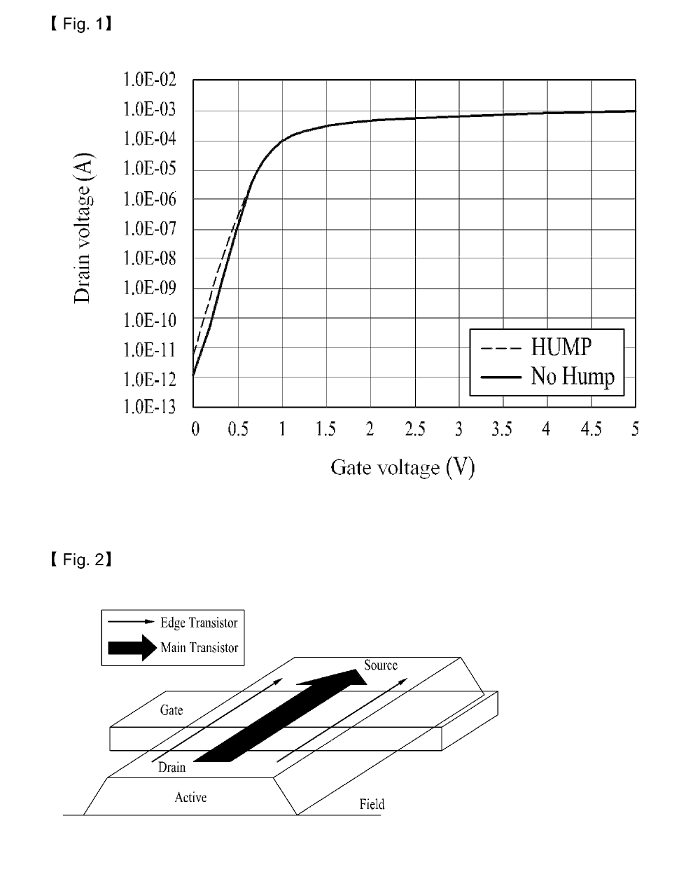

FIG. 2 is a view illustrating an edge transistor and a main transistor;

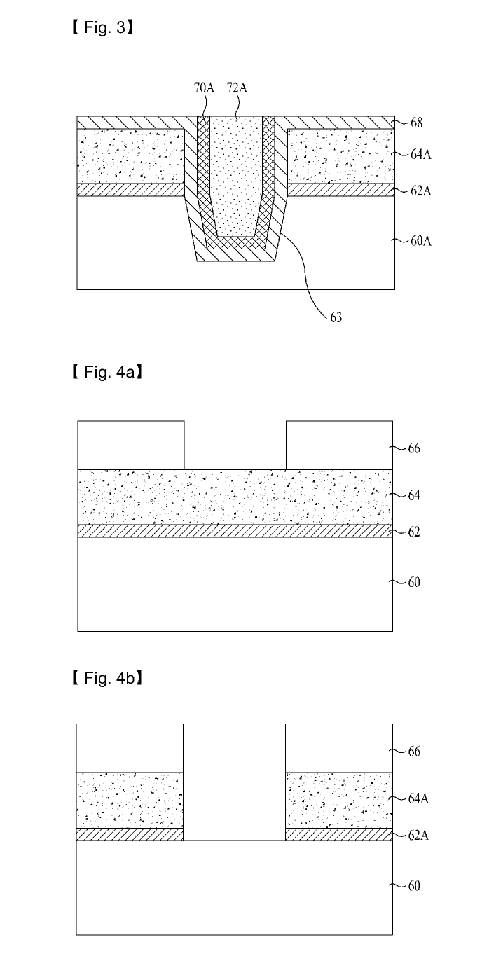

FIG. 3 is a sectional view illustrating a MOS transistor according to an embodiment of the present invention; and

FIGS. 4A to 4G are process sectional views illustrating a method for manufacturing a MOS transistor according to embodiments of the present invention.

### DETAILED DESCRIPTION OF SOME EXAMPLE EMBODIMENTS

In the following detailed description of the embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

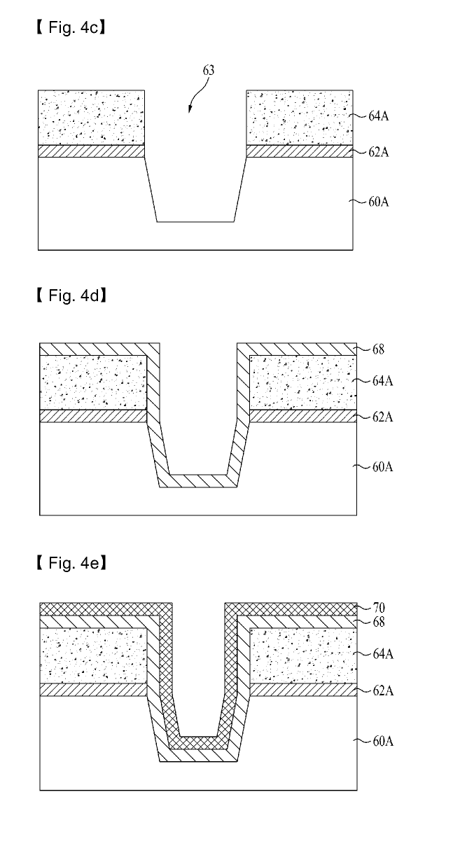

FIG. 3 is a sectional view illustrating a MOS transistor according to an embodiment of the present invention.

The MOS transistor may include a semiconductor substrate 60A, a pad oxide layer 62A, a mask layer 64A, an anti-diffusion layer 68, an oxide layer 70A, and a flattened insulating layer 72A.

Referring to FIG. 3, the pad oxide layer 62A and the mask layer 64A, through which an opening is formed, may be successively stacked on the semiconductor substrate 60A. A partial region of the semiconductor substrate 60A may be exposed via the opening. A trench 63 may be formed in the semiconductor substrate 60A by etching the partial region of the semiconductor substrate 60A, exposed via the opening of the pad oxide layer 62A and the mask layer 64A, using the mask layer 64A as an etching mask.

The anti-diffusion layer 68 and the oxide layer 70A may be successively formed over the entire surface of the semiconductor substrate 60A including the trench 63. In the configuration of FIG. 3, after forming the oxide layer 70A, the oxide may be subjected to flattening until the portion of anti-diffusion layer 68 around a trench forming region, i.e. the portion formed on the mask layer 64A, is exposed. Here, the trench forming region is a region including the trench 63 and the above-described opening.

In a second alternative embodiment, an oxide layer, such as oxide layer 70A, may first be formed over the entire surface of the semiconductor substrate 60A including the trench 63 and, thereafter, the anti-diffusion layer 68 may be formed over the oxide layer.

In accordance with the first embodiment, as shown in FIG. 3, the oxide layer 70A may be formed only on inner wall surfaces of the trench 63 and the opening, rather than being formed over the entire surface of the anti-diffusion layer 68. Specifically, the anti-diffusion layer 68 may be formed not only on the inner wall surfaces of the trench 63 and the opening, but also on the mask layer 64A, and in turn, the oxide layer 70A may be formed only on the portion of anti-diffusion layer 68 formed inside the trench 63 and the opening.

In accordance with another embodiment different than the configuration of FIG. 3, the oxide layer 70A may be first formed over the entire surface of the semiconductor substrate 60A including the trench 63 and, thereafter, the anti-diffusion layer 68 may be formed over the entire surface of the oxide layer 70A. In this embodiment, the oxide layer 70A may be formed not only on the inner wall surfaces of the trench 63 and the opening, but also on the mask layer 64A, and in turn, the anti-diffusion layer 68 may be formed over the entire surface of the oxide layer 70A.

Referring again to the embodiment of FIG. 3, the oxide layer 70A may be formed on the anti-diffusion layer 68 inside the trench 63 and the opening. In addition, the gap-filling insulating layer 72A may be formed on the inner wall surfaces of the trench 63 and the opening, and may be formed-at least during an intermediate processing stage-on the portions of anti-diffusion layer 68 and oxide layer 70A around the trench forming region, i.e., on the mask layer 64A. More particularly, after forming the oxide layer 70A over the entire surface of the anti-diffusion layer 68, an insulating material to gap-fill the trench 63 and the opening may be deposited over the entire surface of the oxide layer 70A. As the gap-filling insulating material is subjected to flattening, the flattened insulating layer 72A may be formed. The flattening may performed on the insulating material and the oxide layer 70A until a surface of the portion of anti-diffusion layer 68 around the trench forming region, i.e. the portion formed on the mask layer 64A, is exposed.

In another embodiment in which the anti-diffusion layer 68 is formed over the oxide layer 70A, the gap-filling insulating layer 72A may be formed inside the trench 63 and the opening and on the portions of the oxide layer 70A and the anti-diffusion layer 68 that are formed around the trench forming region. More particularly, after forming the anti-diffusion layer 68 over the entire surface of the oxide layer 70A, the insulating material may deposited over the entire surface of the anti-diffusion layer 68, to gap-fill the trench 63 and the opening. As the gap-filling insulating material is subjected to flattening, the flattened insulating layer 72A may be formed.

Hereinafter, example methods for manufacturing the MOS transistor will be described with reference to the accompanying drawings.

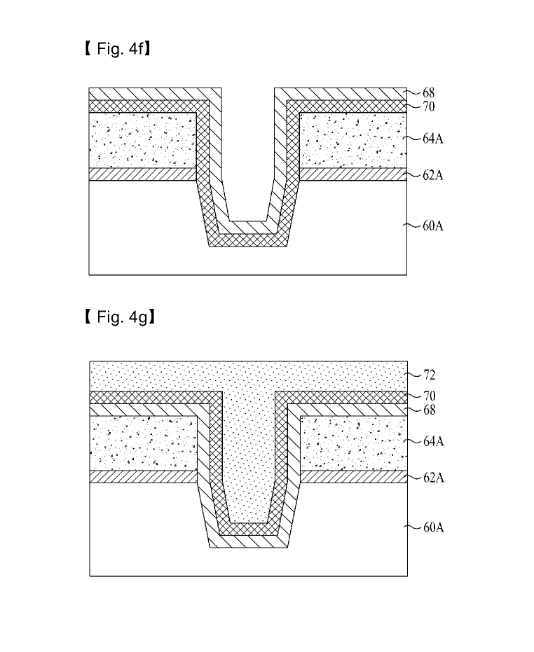

FIGS. 4A to 4G are process sectional views illustrating example methods for manufacturing a MOS transistor.

Referring to FIG. 4A, a pad oxide layer 62 and a mask layer 64 may be successively stacked over a semiconductor substrate 60. The mask layer 64 may be a nitride layer.

Thereafter, a photosensitive layer pattern 66 may be formed on the mask layer 64, to form the trench 63 in the semiconductor substrate 60.

Referring to FIG. 4B, the pad oxide layer 62 and the mask layer 64 may be patterned using the photosensitive layer pattern 66, to expose a trench forming region of the semiconductor substrate 60. Specifically, the pad oxide layer 62 and the mask layer 64 may be etched using the photosensitive layer pattern 66 as an etching mask, to expose a region of the semiconductor substrate 60 where the trench 63 will be formed.

Referring to FIG. 4C, the exposed region of the semiconductor substrate 60 may be etched using the patterned mask layer 64A and pad oxide layer 62A as an etching mask, forming the trench 63 in the semiconductor substrate 60. Thereby, the semiconductor substrate 60A having the trench 63 is formed, and an opening region is defined by the patterned pad oxide layer 62 and mask layer 64A.

Referring to FIGS. 4D to 4F, the anti-diffusion layer 68 and the oxide layer 70 may be formed over the entire surface of the semiconductor substrate 60A including the trench 63.

According to one embodiment, the anti-diffusion layer 68 may be first formed over the entire surface of the semiconductor substrate 60A including the trench 63 by depositing a thermal oxide, for example, alumina, to a thickness from tens to hundreds of angstroms via Atomic Layer Deposition (ALD). Here, the alumina may have stable material characteristics and is denoted by AlₓO_{y} (where, X may be 2, and Y may be 3). The anti-diffusion layer 68 (e.g., Al₂O₃) may serve to prevent boron from being diffused toward the insulating layer 72A, which is to serve as a gap-filling material. Accordingly, the anti-diffusion layer 68 can maintain a substantially uniform well dopant concentration in an HV NMOS transistor during subsequent thermal processing. As a result, formation of an edge transistor can be substantially prevented, resulting in a reduction in leakage current.

Referring to FIG. 4E, an oxide layer 70 may be formed over the entire surface of the anti-diffusion layer 68 via a high-temperature thermal process.

Referring to FIGS. 4D and 4E, after forming the anti-diffusion layer 68, the oxide layer 70 may be formed on the anti-diffusion layer 68. The oxide layer 70 may be formed to improve adhesion between the anti-diffusion layer 68 and the subsequently formed insulating layer 72A.

However, in accordance with another embodiment, as shown in FIG. 4F, after first forming the oxide layer 70 over the entire surface of the semiconductor substrate 60A including the trench 63, the anti-diffusion layer 68 may be formed over the entire surface of the oxide layer 70.

The oxide layer 70 may be formed under a process condition of 900° C. or more, and the deposition of Al₂O₃ as the anti-diffusion layer 68 using ALD may be performed at a lower temperature of 300° C. or less. The deposition temperature of Al₂O₃ using ALD may be lower than the formation temperature of the oxide layer 70 to maintain a uniform well dopant concentration in the HV NMOS transistor.

Although some of the foregoing description pertains to the anti-diffusion layer 68 being first formed and, thereafter, the oxide layer 70 being formed on the anti-diffusion layer 68, as shown in FIGS. 4D and 4E, it will be appreciated that the foregoing descriptionequally pertains to the case where the anti-diffusion layer 68 is formed after forming the oxide layer 70, as shown in FIG. 4F.

Referring to FIG. 4G, an insulating material to gap-fill the trench forming region including the trench 63 and the opening may be deposited over the entire surface of the semiconductor substrate 60A.

More particularly, in the configuration of FIG. 3, an insulating material 72, such as an oxide to gap-fill the trench forming region, may be deposited on the oxide layer 70. Then, the insulating material 72 and the oxide layer 70 may be flattened via, e.g., Chemical Mechanical Planarization (CMP), forming the flattened insulating layer 72A as shown in FIG. 3. The anti-diffusion layer 68 may be used as a stopping layer in the CMP process.

As apparent from the above description, embodiments of the present invention provide a MOS transistor and a method for manufacturing the transistor, which can reduce leakage current, among other things, thereby achieving improved characteristics of transistor products.

While the present invention has been described with respect to example embodiments, it will be apparent to those skilled in the art that various changes and modifications may be made without departing from the scope of the present invention as defined in the following claims.

What is claimed is:

1. A method for manufacturing a Metal Oxide Semiconductor (MOS) transistor comprising:
successively stacking a pad oxide layer and a mask layer on a semiconductor substrate;
patterning the pad oxide layer and the mask layer, to expose a trench forming region of the semiconductor substrate;
forming a trench in the semiconductor substrate by etching the exposed trench forming region; and
forming an anti-diffusion layer and an oxide layer over the entire surface of the semiconductor substrate including the trench.

2. The method according to claim 1, wherein the step of forming the anti-diffusion layer and the oxide layer comprises:
forming the oxide layer over the entire surface of the semiconductor substrate including the trench; and
forming the anti-diffusion layer over the entire surface of the oxide layer.

3. The method according to claim 1, wherein the step of forming the anti-diffusion layer and the oxide layer comprises:
forming the anti-diffusion layer over the entire surface of the semiconductor substrate including the trench; and
forming the oxide layer over the entire surface of the anti-diffusion layer.

4. The method according to claim 3, wherein the anti-diffusion layer is formed by depositing alumina over the entire surface of the semiconductor substrate including the trench.

5. The method according to claim 4, wherein the alumina is deposited via Atomic Layer Deposition (ALD).

6. The method according to claim 3, further comprising:
depositing an insulating material over the entire surface of the oxide layer to gap-fill the trench forming region; and
flattening the insulating material and the oxide layer until the anti-diffusion layer around the trench forming region is exposed.

7. The method according to claim 6, wherein the insulating material is an oxide.

8. The method according to claim 1, further comprising:
depositing an insulating material to gap-fill the trench forming region over the entire surface of the semiconductor substrate; and
flattening the entire surface of the semiconductor substrate including the insulating material, to form an insulating layer in the trench forming region.

9. A Metal Oxide Semiconductor (MOS) transistor comprising:
a pad oxide layer and a mask layer successively stacked on a semiconductor substrate and having an opening to expose the semiconductor substrate;
a trench formed by etching a region of the semiconductor substrate exposed through the opening;
an anti-diffusion layer, a first portion of which is formed inside the trench and the opening and a second portion of which is formed on the mask layer;
an oxide layer formed on the first portion of the anti-diffusion layer formed inside the trench and the opening; and
an insulating layer gap-filled in the trench and the opening, the trench and the opening including the first portion of the anti-diffusion layer and the overall oxide layer.

10. The transistor according to claim 9, wherein the anti-diffusion layer is made of alumina.

11. A Metal Oxide Semiconductor (MOS) transistor comprising:
a pad oxide layer and a mask layer successively stacked on a semiconductor substrate and having an opening to expose the semiconductor substrate;
a trench formed by etching a region of the semiconductor substrate exposed through the opening;
an oxide layer, a first portion of which is formed inside the trench and the opening and a second portion of which is formed on the mask layer;
an anti-diffusion layer formed on the first and second portions of the oxide layer; and
an insulating layer gap-filled in the trench and the opening, the trench and the opening including the first portion of the oxide layer and a corresponding portion of the anti-diffusion layer.

12. The transistor according to claim 11, wherein the anti-diffusion layer is made of alumina.
